(19) United States
(12) Patent Application Publication
(10) Pub. No.: US 2023/0228796 A1
(43) Pub. Date: Jul. 20, 2023

(54) CONTROLLER AND A METHOD TO OPERATE A TEMPERATURE SENSOR

(71) Applicant: Infineon Technologies AG, Neubiberg (DE)

(72) Inventors: Chern Sia Phillip Lim, Singapore (SG); Chin Yeong Koh, Singapore (SG); Jaafar Mejri, Ottobrunn (DE)

(21) Appl. No.: 18/155,460

(22) Filed: Jan. 17, 2023

(30) Foreign Application Priority Data
Jan. 20, 2022 (DE) 102022101328.6

(51) Int. Cl. G01R 19/10; G01K 7/01

(52) U.S. Cl. CPC G01R 19/10; G01K 7/01

(57) ABSTRACT

In accordance with an embodiment, a controller to operate a temperature sensor comprising a transistor assembly is configured to: cause a generation of a first pair of bias currents comprising a first bias current and a second bias current for the transistor assembly; determine a first diode voltage difference of the transistor assembly corresponding to the first pair of bias currents; cause a generation of a second pair of bias currents comprising a third bias current and a fourth bias current for the transistor assembly; determine a second diode voltage difference for the transistor assembly corresponding to the second pair of bias currents; and compare the first diode voltage difference and the second diode voltage difference to determine at least one of functional information and performance information of the temperature sensor.

This application claims the benefit of German Patent Application No. 102022101328.6, filed on Jan. 20, 2022, which application is hereby incorporated herein by reference.

### TECHNICAL FIELD

Examples relate to a controller and a method to operate a temperature sensor.

### BACKGROUND

Temperature sensors are typically used for temperature monitoring or provide a means of temperature-dependent control of other circuit blocks. Often, they are integrated in the same die (die temperature sensors—DTS) as the circuit blocks they are to monitor or control.

When used for temperature monitoring, temperature sensors may be critical for functional safety whereby devices have to be brought to a safe state upon detection of an over-temperature condition. Defects in the die temperature circuit might lead to either false temperature warnings, or worse, missing temperature warnings, which in turn may lead to device damage. When used for temperature-dependent control, temperature sensors can be used to improve the performance of other analog circuits by providing a means of temperature-dependent compensation trimming. Likewise, they can be used in temperature-aware load-balancing operations for performance optimization. While temperature sensors may provide for increased functional safety and performance of other devices and circuits, being able to monitor the state and performance of the temperature sensors themselves is equally important.

A self-contained test scheme for temperature sensors would be able to detect defects (both catastrophic and drift-type) in the field, which may be caused by process, aging or stress. On the observation of a defect of any kind, one may trigger remedial actions to either correct a performance issue or avoid irreversible damage in an over-temperature condition. Another aspect where a self-test scheme would be useful is during calibration of a temperature sensor. High-precision temperature sensors may require calibration to achieve the required accuracy. As calibration requires accurate information of the true temperature of a die the temperature sensor is embedded in, one technique is to use other on-chip circuitry (often part of the die temperature sensor) as a calibration reference for a DTS. With such an approach, there is no efficient feedback mechanism to ascertain the quality of the calibration, and a defect in the temperature sensor at the time of the calibration would compromise the quality of the calibration, and hence the calibrated accuracy of the temperature sensor itself.

Another possibility to detect latent faults in a temperature sensor for functional safety purposes is to use redundancy, i.e. instantiating more than one temperature sensor in a product, while the readouts cross-checks among the multiple instances. Redundancy, however, incurs additional power/area, as well as either additional hardware or processor loading to implement the cross-checking.

Hence, there is a demand for a reliable and more efficient self-testing scheme for a temperature sensor.

### SUMMARY

An example relates to a controller to operate a temperature sensor comprising a transistor assembly. The controller is configured to cause generation of a first pair of bias currents comprising a first bias current and a second bias current for the transistor assembly. The controller determines a first diode voltage difference of the transistor assembly corresponding to the first pair of bias currents. Further, the controller is configured to cause generation of a second pair of bias currents comprising a third bias current and a fourth bias current for the transistor assembly and to determine a second diode voltage difference for the transistor assembly corresponding to the second pair of bias currents. The controller compares the first diode voltage difference and the second diode voltage difference to determine at least one of functional information and performance information of the temperature sensor. Comparing two diode voltage differences may allow to conclude on a functionality of the temperature sensor since a relation between the voltage differences may be essentially independent from environmental conditions and from further conditions and circuitry affecting a single measurement. Functional information and/or the performance information may, therefore, be determined in every operating condition, be it during manufacturing or in the field.

Providing the same benefits, a method for determining at least one of functional and performance information of a temperature sensor comprises determining a first diode voltage difference of a transistor assembly corresponding to a first pair of bias currents and deter-mining a second diode voltage difference of the transistor assembly corresponding to a second pair of bias currents. The method further comprises comparing the first diode voltage difference and the second diode voltage difference to determine at least one of the functional and the performance information.

### BRIEF DESCRIPTION OF THE DRAWINGS

Some examples of apparatuses and/or methods will be described in the following by way of example only, and with reference to the accompanying figures, in which

FIG. 1 schematically illustrates an embodiment of a controller to operate a temperature sensor comprising a transistor assembly;

FIG. 2 schematically illustrates an embodiment of a controller to operate a temperature sensor comprising a differential transistor assembly;

FIG. 3 illustrates an example of a readout chain of a temperature sensor; and

FIG. 4 schematically illustrates an embodiment of a method to operate a temperature sensor.

### DETAILED DESCRIPTION OF ILLUSTRATIVE EMBODIMENTS

Some examples are now described in more detail with reference to the enclosed figures. However, other possible examples are not limited to the features of these embodiments described in detail. Other examples may include modifications of the features as well as equivalents and alternatives to the features. Furthermore, the terminology used herein to describe certain examples should not be restrictive of further possible examples.

Throughout the description of the figures, same or similar reference numerals refer to same or similar elements and/or features, which may be identical or implemented in a modified form while providing the same or a similar function. The thickness of lines, layers and/or areas in the figures may also be exaggerated for clarification.

When two elements A and B are combined using an “or”, this is to be understood as disclosing all possible combinations, i.e. only A, only B as well as A and B, unless expressly defined otherwise in the individual case. As an alternative wording for the same combinations, “at least one of A and B” or “A and/or B” may be used. This applies equivalently to combinations of more than two elements.

If a singular form, such as “a”, “an” and “the” is used and the use of only a single element is not defined as mandatory either explicitly or implicitly, further examples may also use several elements to implement the same function. If a function is described below as implemented using multiple elements, further examples may implement the same function using a single element or a single processing entity. It is further understood that the terms “include”, “including”, “comprise” and/or “comprising”, when used, describe the presence of the specified features, integers, steps, operations, processes, elements, components and/or a group thereof, but do not exclude the presence or addition of one or more other features, integers, steps, operations, processes, elements, components and/or a group thereof.

Some embodiments relate to a controller and a method to operate a temperature sensor and to, for example, determine at least one of functional information and performance information of the temperature sensor.

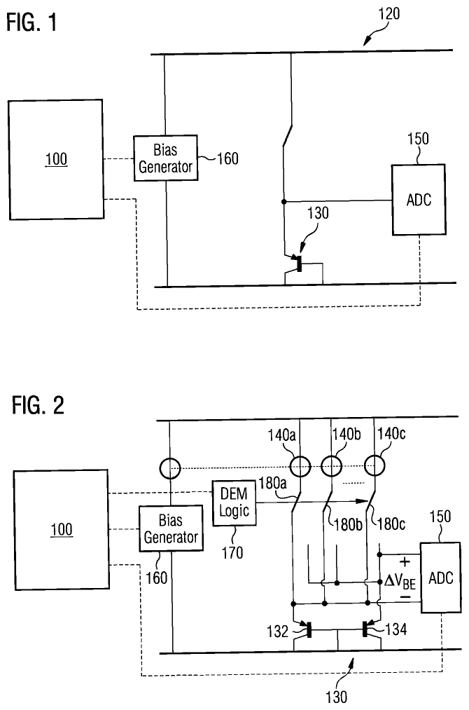

FIG. 1 schematically illustrates an embodiment of a controller 100 to operate a temperature sensor 120 comprising a transistor assembly 130. In the example of a temperature sensor 120 illustrated in FIG. 1, the transistor assembly has a single PNP transistor.

Temperature sensors can use the temperature dependency of a diode voltage to determine the temperature of a substrate or a die at the position of the diode. A bipolar transistor can be viewed as a double diode and, hence, a voltage across one of the two diodes of the bipolar transistor may be used to measure temperatures. For example, the Base-Emitter Voltage V_{BE} of a bipolar transistor is depending on a thermal Voltage V_{T} as well as on the Collector current I_{c} and the reverse current Iₛ. The reverse current is temperature dependent itself in a complex manner, while the thermal Voltage V_{T} depends linearly on the temperature. Determining a voltage difference ΔV_{BE(1,2)} of the Base-Emitter Voltages V_{BE} at a first bias current I_{C1} and a second bias current I_{C2} allows to eliminate the dependency on Iₛ and, therefore, determining the temperature using the linear dependency of V_{T} on T:

$${V}_{B E} = n {V}_{T} ln ( \frac{{I}_{C}}{{I}_{S}} ) ⇒ Δ {V}_{B E ( 1 , 2 )} = {V}_{B E 1} - {V}_{B E 2} = n {V}_{T} ln ( \frac{{I}_{C 1}}{{I}_{C 2}} ) .$$

The bias current ratio

$${α}_{1 , 2} = \frac{{I}_{C 1}}{{I}_{C 2}}$$

is so used to perform a single temperature measurement. If one further determines a second diode voltage difference ΔV_{BE(3,4)} for the transistor assembly that corresponds to a second pair of bias currents comprising a third bias current I_{C3} and a fourth bias current I_{C4}, one can derive a quantity R being independent from temperature T.

$${R}_{0} = \frac{Δ {V}_{B E ( 1 , 2 )}}{Δ {V}_{B E ( 3 , 4 )}} = \frac{ln ( {α}_{1 , 2} )}{ln ( {α}_{3 , 4} )} .$$

If the temperature sensor does not exhibit any hardware damages, the comparison of the first and second diode voltage differences ΔV_{BE(1,2)} and ΔV_{BE(3,4)} according to the previous relation is expected to give a constant result irrespective of the temperature the temperature sensor is operated in. Comparing the first diode voltage difference and the second diode voltage difference, therefore, allows for the efficient determination of functional information and/or performance information of the temperature sensor, independent from the environmental conditions the test is performed in. While using the voltage difference V_{BE1}−V_{BE2} of two Base-Emitter Voltages results in a particularly instructive example, further embodiments may be based on a Voltage difference determined from an arbitrary linear combination of multiple base emitter voltages V_{BEx} generated using different bias currents I_{cx}, respectively.

The observation that ratio R₀ is outside of an expected range may be caused by a functional error or by performance degradation. A functional error may be a situation where the temperature sensor is not working at all or at least not according to its intended logic function so that one should not use the sensor reading at all. Performance degradation may occur during operation and result in the temperature sensor not or no longer working within an acceptable range of accuracy. For example, a power source used to generate the bias currents may be faulty and no longer generating the bias currents accurately, resulting in the temperature sensor reading becoming inaccurate. Similarly, leaky or inoperative switches within the temperature sensor may result in current variations having the same effect. Depending on the extent of performance degradation one may decide to accept a larger error of the temperature reading of the temperature sensor or to disregard the reading at all. One may, for example, distinguish between a functional error and performance degradation by the amount the ratio R₀ deviates from the expected value or range. To this end, the information gathered by comparing the first diode voltage difference and the second diode voltage difference may also be denoted functional information and performance information.

In order for the controller 100 to check on at least one of the functional information and the performance information of the temperature sensor, the controller 100 can cause the generation of a first pair of bias currents comprising the first bias current I_{C1} and the second bias current I_{C2}. In the event of a temperature sensor 110 as illustrated in FIG. 1, the controller 100 may steer a bias generation circuit 160 that generates the bias current for the transistor assembly 130 to sequentially output the first bias current I_{C1} and the second bias current I_{C2}. Likewise, the controller 100 is configured to cause generation of a second pair of bias currents comprising a third bias current I_{C3} and a fourth bias current I_{C4} for the transistor assembly. The ratio between the first bias current and the second bias current may be different from a ratio between the third bias current and the fourth bias current. Further, the controller is capable to determine the first diode voltage difference ΔV_{BE(1,2)} of the transistor assembly corresponding to the first pair of bias currents and the second diode voltage difference ΔV_{BE(3,4)} for the transistor assembly corresponding to the second pair of bias currents. If the temperature sensor comprises an Analog-to-Digital converter 150 (ADC) as illustrated in FIG. 1 to digitize the Base-Emitter Voltage of the transistor as illustrated in FIG. 1, the controller 100 may be coupled to the ADC 150 to receive the digital codes representing the Base-Emitter Voltage. For example, a Delta-Sigma-ADC may be used in some embodiments to generate the digital code.

The controller 100 compares the first diode voltage difference ΔV_{BE(1,2)} and the second diode voltage difference ΔV_{BE(3,4)} to determine at least one of functional and performance information of the temperature sensor. For example, the controller may be configured to calculate the ratio R₀ as illustrated before. In this event, the controller 100 can be configured to determine that the temperature sensor (120) is in a condition free of defects if a ratio of the first diode voltage difference and the second diode voltage difference is within an expected range. However, further embodiments may likewise use other metrics or calculations to arrive at similar or identical conclusions by comparing the first diode voltage difference and the second diode voltage difference.

According to some embodiments, the temperature sensor 120 is contained on a semiconductor die and the semiconductor die further contains a functional circuitry, the temperature sensor 120 being configured to monitor the temperature of the functional circuitry. The temperature sensor 120 can then be used as a die temperature sensor for the functional device offering both, testing its own functionality during production or during regular operation in the field.

While the embodiment of FIG. 1 has been described in connection with a temperature sensor using a bipolar transistor, further embodiments may likewise control other temperature sensors evaluating other diode voltages, such as for example, the voltage across a single diode or the gate source voltage of a field effect transistor (FET).

FIG. 2 schematically illustrates a controller 100 to operate a temperature sensor having a differential transistor assembly. As far as the aspects relating to the testing of the temperature sensor are concerned, the operation of the controller 100 has already been described while referring to FIG. 1. However, minor differences may exist in the way the sensor reading is determined and with respect to the circuit elements the controller 100 is capable to control and the following description is restricted to those additional aspects.

The controller 100 of FIG. 2 controls a differential transistor assembly 130, comprising a first transistor 132 and a second transistor 134. The difference of the Base Emitter Voltage of the first transistor 132 and the second transistor 134 (which are diode voltages across the diodes formed by the Bases and the Emitters of the PNP transistors) is digitized by an ADC 150, which is a Delta-Sigma ADC in the illustrated implementation. The bias generator 160 defines a unit current that is replicated multiple times by unit current sources 140a . . . 140c. For example, the unit current sources 140a . . . 140c may be individual current sources controlled by the bias generator 160 or the unit current sources 140a . . . 140c may comprise current mirrors to replicate a bias current generated by the bias generator 160.

Multiple switches 180a . . . 180c serve to connect every current source 140a, . . . , 140c to either the first transistor 132 or the second transistor 134 to generate bias currents for the transistors 132 and 134 in multiples of unit currents. A switch controller (DEM Logic) 170 serves to operate the switches 180a, 180c to generate the first bias current I_{C1} and the second bias current I_{C2} as well as the third bias current I_{C3} and a fourth bias current I_{C4}. Applying the first bias current I_{C1} to one of the transistors 132 or 134 and the second bias current I_{C2} to the other one of the transistors simultaneously generates the first voltage difference ΔV_{BE(1,2)} at an input of ADC 150. As compared to the temperature sensor in FIG. 1, those two bias currents do not have to be generated sequentially. In other words, during operation, the controller 100 causes a first number of unit current sources 140a, 140b, 140c to connect to the transistor assembly 130 to provide the first bias current and a second number of unit current sources to connect to the transistor assembly (130) to provide the second bias current. In particular, the controller causes the first number of unit current sources 140a, 140b, 140c to connect to the first transistor 132 within the transistor assembly 130 and the second number of unit current sources 140a, 140b, 140c to connect to a second transistor 134 within the transistor assembly 130.

If, for example, there exist 16 unit current sources, a ratio

$${α}_{1 , 2} = \frac{{I}_{C 1}}{{I}_{C 2}} = 1 / 15$$

could be used for a temperature measurement or, for example, a ratio of 2/14 or of 3/13.

In other words, the array of switches 180a . . . 180c steers bias currents from a bank of current sources 140a, 140b, and 140c into a PNP pair. Using a Delta-Sigma ADC which averages multiple sampling periods, potential mismatch in the current sources 140a, 140b, 140c may be compensated by driving the switches 180a, . . . , 180c using Dynamic Element Matching (DEM). That is, the switches connecting to a single transistor are changed dynamically, while maintaining the ratio

$${α}_{1 , 2} = \frac{{I}_{C 1}}{{I}_{C 2}}$$

at all times.

Controlling the switches 180a . . . 180c appropriately can also be used to compensate mismatch in the PNP pair by system chop. That is, the first bias current is provided to the first transistor 132 for the first half of the sample periods used to generate a single ADC output while the first bias current is provided to the second transistor 134 for the second half of the sample periods. In other words, if system chop is implemented, the controller further causes the first number of unit current sources 140a, 140b, 140c to connect to the second transistor 134 and the second number of unit current sources 140a, 140b, 140c to connect to the first transistor 132 when causing the generation of the first pair of bias currents.

The second measurement with the third bias current I_{C3} and a fourth bias current I_{C4} is likewise controlled by the controller 100 to ultimately compare the voltage differences by means of the relation

$${R}_{0} = \frac{Δ {V}_{B E ( 1 , 2 )}}{Δ {V}_{B E ( 3 , 4 )}} = \frac{ln ( {α}_{1 , 2} )}{ln ( {α}_{3 , 4} )} ,$$

and to conclude on the functional information and/or performance information of the temperature sensor 120. For example, a deviation of the expected ratio R₀ may be observed if a logic gate of the temperature sensor 120 no longer provides it's intended logic function or if one or more of the switches 180a . . . 180c are leaky.

In summary, the proposed controller 100 is configured to detect analog defects that could compromise the quality of calibration that might conventionally not be detected during production testing. Furthermore, the controller 100 may be used to perform tests in the field to detect defects occurring during normal operation, such as for example degradation of semiconductor circuitry, e.g. due to aging. For example, semiconductor switches may become leakier over time, which could be detected by an embodiment of a controller 100. The controller 100 implementing the self-test scheme largely re-uses existing hardware of the temperature sensor, hence providing an additional safety mechanism option that is power/area efficient.

The determination of the ratio of the readouts and the controller may, for example, be implemented by either hardware or firmware. In an existing controller, the functionality may be added by a software or by a firmware update.

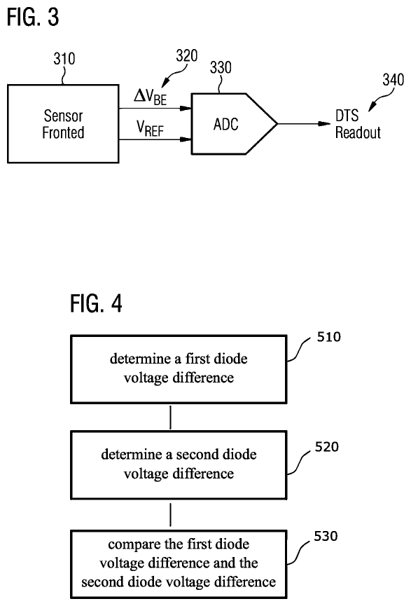

FIG. 3 schematically illustrates a readout chain for a temperature sensor to demonstrate the high diagnostic coverage provided by an embodiment of the present disclosure.

The temperature sensor frontend 310 comprises the transistor assembly. The diode voltage differences 320 of the transistors are digitized using an ADC 330 to generate a digitized readout 340. Typically, a reference voltage is also provided to the ADC 330, essentially setting its dynamic range. The following considerations will show that the proposed self-test scheme performed by a controller of the temperature sensor covers the entire illustrated readout chain including ADC 330.

Assuming a transfer function of for the readout chain D to be

$$D = \frac{K \cdot Δ {V}_{B E}}{{V}_{R E F}} ,$$

the ratio R computes to:

$$R = \frac{{D}_{1 , 2}}{{D}_{3 , 4}} = \frac{\frac{K \cdot Δ {V}_{BE ( 1 , 2 )}}{{V}_{R E F}}}{\frac{K \cdot Δ {V}_{B E ( 3 , 4 )}}{{V}_{R E F}}} = \frac{Δ {V}_{B E ( 1 , 2 )}}{{V}_{BE ( 3 , 4 )}} = \frac{ln ( {α}_{1 , 2} )}{ln ( {α}_{3 , 4} )}$$

The ratio R is not only independent of PVT but also independent of variations in the ADC reference voltage V_{REF}. In the above formula, K is a constant scaling factor depending on the design.

The determined functional information or the performance information may, for example, indicate that the temperature sensor is not defective if the readout ratio is within the following limits:

R₀−ΔR≤R<R₀−ΔR

where AR is a permissible tolerance spread for R.

Since the embodiments discussed herein re-use almost all key analog blocks in the signal-processing path, it provides a high coverage of analog defects, including both the sensor frontend and ADC. This scheme also measures precise analog metrics and not only function, making it well suited to detect not only catastrophic, but also marginal or drift-type defects that come from fabrication, aging or stress. Such defect types can also include failure of the mismatch-compensation circuits (i.e., DEM or ADC chop).

FIG. 4 schematically illustrates an embodiment of a method to operate a temperature sensor as it may be performed by a controller illustrated in FIG. 1 or 2.

The method comprises determining a first diode voltage difference 510 of a transistor assembly corresponding to a first pair of bias currents and determining a second diode voltage difference 520 of the transistor assembly corresponding to a second pair of bias currents.

Further, the method comprises comparing the first diode voltage difference and the second diode voltage difference 530 to determine the at least one of the functional and the performance information.

In summary, the embodiments described herein provide an efficient and self-contained test scheme to detect analog defects in temperature sensors (e.g., in a DTS) that uses the same analog blocks (sensor frontend and ADC) to derive two different readouts that maintain a fixed ratio of diode voltages, e.g. across PVT. The temperature sensor readout is often some scaled version of ΔV_{BE}, and with ΔV_{BE} being proportional to the ratio of a pair of bias currents applied on the transistor of the temperature sensor (e.g., a PNP bipolar transistor), the ratio of a pair of ΔV_{BE}'s generated from different bias current ratios will be fixed, which can be used for self-testing.

The embodiments described herein may be used in various applications. For production, they may offer yield improvement at backend by providing an efficient method to filter devices with defective temperature sensors already at frontend. For example, in automotive products, they may also offer an alternative safety mechanism for functional safety to detect analog defects in the temperature sensor in the field, providing an alarm to bring the device/system to a safe state. This could potentially replace the redundancy mechanism currently employed for existing products using temperature sensors, in particular a die temperature sensor, and provide area/power savings.

The aspects and features described in relation to a particular one of the previous examples may also be combined with one or more of the further examples to replace an identical or similar feature of that further example or to additionally introduce the features into the further example.

Examples may further be or relate to a (computer) program including a program code to execute one or more of the above methods when the program is executed on a computer, processor or other programmable hardware component. Thus, steps, operations or processes of different ones of the methods described above may also be executed by programmed computers, processors or other programmable hardware components. Examples may also cover program storage devices, such as digital data storage media, which are machine-, processor- or computer-readable and encode and/or contain machine-executable, processor-executable or computer-executable programs and instructions. Program storage devices may include or be digital storage devices, magnetic storage media such as magnetic disks and magnetic tapes, hard disk drives, or optically readable digital data storage media, for example. Other examples may also include computers, processors, control units, (field) programmable logic arrays ((F)PLAs), (field) programmable gate arrays ((F)PGAs), graphics processor units (GPU), application-specific integrated circuits (ASICs), integrated circuits (ICs) or system-on-a-chip (SoCs) systems programmed to execute the steps of the methods described above.

It is further understood that the disclosure of several steps, processes, operations or functions disclosed in the description or claims shall not be construed to imply that these operations are necessarily dependent on the order described, unless explicitly stated in the individual case or necessary for technical reasons. Therefore, the previous description does not limit the execution of several steps or functions to a certain order. Furthermore, in further examples, a single step, function, process or operation may include and/or be broken up into several sub-steps, -functions, -processes or -operations.

If some aspects have been described in relation to a device or system, these aspects should also be understood as a description of the corresponding method. For example, a block, device or functional aspect of the device or system may correspond to a feature, such as a method step, of the corresponding method. Accordingly, aspects described in relation to a method shall also be understood as a description of a corresponding block, a corresponding element, a property or a functional feature of a corresponding device or a corresponding system.

The following claims are hereby incorporated in the detailed description, wherein each claim may stand on its own as a separate example. It should also be noted that although in the claims a dependent claim refers to a particular combination with one or more other claims, other examples may also include a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

What is claimed is:

1. A controller to operate a temperature sensor comprising a transistor assembly, the controller configured to:
cause a generation of a first pair of bias currents comprising a first bias current and a second bias current for the transistor assembly;
determine a first diode voltage difference of the transistor assembly corresponding to the first pair of bias currents;
cause a generation of a second pair of bias currents comprising a third bias current and a fourth bias current for the transistor assembly;
determine a second diode voltage difference for the transistor assembly corresponding to the second pair of bias currents; and
compare the first diode voltage difference and the second diode voltage difference to determine at least one of functional information and performance information of the temperature sensor.

2. The controller of claim 1, wherein the controller is configured to indicate that the temperature sensor is in a condition free of defects when a ratio of the first diode voltage difference and the second diode voltage difference is within an expected range.

3. The controller of claim 1, wherein a ratio between the first bias current and the second bias current is different from a ratio between the third bias current and the fourth bias current.

4. The controller of claim 1, wherein causing the generation of the first pair of bias currents causes a first number of unit current sources to connect to the transistor assembly to provide the first bias current and a second number of unit current sources to connect to the transistor assembly to provide the second bias current.

5. The controller of claim 4, wherein causing the generation of the first pair of bias currents causes the first number of unit current sources to connect to a first transistor within the transistor assembly and the second number of unit current sources to connect to a second transistor within the transistor assembly.

6. The controller of claim 5, wherein causing the generation of the first pair of bias currents further causes the first number of unit current sources to connect to the second transistor and the second number of unit current sources to connect to the first transistor.

7. The controller of claim 1, wherein the temperature sensor further comprises an analog-to-digital converter configured to convert the first diode voltage difference and the second diode voltage difference to digital codes.

8. The controller of claim 1, wherein the temperature sensor is configured to monitor a temperature of a functional circuit, and wherein the temperature sensor and the functional circuit are disposed on a same semiconductor die.

9. The controller of claim 1, wherein the first diode voltage difference is a first base emitter voltage difference of the transistor assembly and the second diode voltage difference is a second base emitter voltage difference of the transistor assembly.

10. A method for determining functional information or performance information of a temperature sensor, the method comprising:
determining a first diode voltage difference of a transistor assembly corresponding to a first pair of bias currents;
determining a second diode voltage difference of the transistor assembly corresponding to a second pair of bias currents; and
comparing the first diode voltage difference and the second diode voltage difference to determine the functional information or the performance information.

11. The method of claim 10, wherein comparing the first diode voltage difference and the second diode voltage difference comprises calculating a ratio of the first diode voltage difference and the second diode voltage difference.

12. The method of claim 11, further comprising indicating that the temperature sensor is determined to be in a condition free of defects when the ratio is within a predetermined range.

13. The method of claim 10, wherein a ratio between the first pair of bias currents is different from a ratio between the second pair of bias currents.

14. The method of claim 10, further comprising:
causing a generation of the first pair of bias currents by causing a first number of unit current sources to connect to the transistor assembly to provide a first bias current of the first pair of bias currents and causing a second number of unit current sources to connect to the transistor assembly to provide a second bias current of the first pair of bias currents.

15. The method of claim 14, wherein causing the generation of the first pair of bias currents causes the first number of unit current sources to connect to a first transistor within the transistor assembly and the second number of unit current sources to connect to a second transistor within the transistor assembly.

16. The method of claim 15, wherein causing the generation of the first pair of bias currents further causes the first number of unit current sources to connect to the second transistor and the second number of unit current sources to connect to the first transistor.

17. The method of claim 15, further comprising converting the first diode voltage difference and the second diode voltage difference to digital codes.

18. A non-transitory computer readable medium having stored thereon instructions that, when executed by a processor, causes the processor to:
receive a measurement of a first diode voltage difference of a transistor assembly corresponding to a first pair of bias currents;
receive a measurement of a second diode voltage difference of the transistor assembly corresponding to a second pair of bias currents; and
comparing the first diode voltage difference and the second diode voltage difference to determine functional information or performance information of a temperature sensor.

19. The non-transitory computer readable medium of claim 18, wherein comparing the first diode voltage difference and the second diode voltage difference comprises calculating a ratio of the first diode voltage difference and the second diode voltage difference.

20. The non-transitory computer readable medium of claim 19, wherein the instructions, when executed by the processor, further cause the processor to indicate that the temperature sensor is determined to be in a condition free of defects when the ratio is within a predetermined range.
